(19) United States
(12) Patent Application Publication
(10) Pub. No.: US 2026/0101778 A1
(43) Pub. Date: Apr. 9, 2026

(54) ELECTRONIC DEVICE AND MANUFACTURING METHOD THEREOF

(71) Applicant: Innolux Corporation, Miaoli County (TW)

(72) Inventors: Chia-Ping Tseng, Miaoli County (TW); Hung-Wen Li, Miaoli County (TW); Ju-Li Wang, Miaoli County (TW)

(73) Assignee: Innolux Corporation, Miaoli County (TW)

(21) Appl. No.: 19/332,064

(22) Filed: Sep. 18, 2025

Related U.S. Application Data
(60) Provisional application No. 63/704,566, filed on Oct. 8, 2024.

(30) Foreign Application Priority Data
May 23, 2025 (CN) 202510674555.2

(51) Int. Cl. H01L 23/538; H01L 21/48; H01L 23/00; H01L 23/498; H01L 25/065

(52) U.S. Cl. CPC H10W 70/611; H10W 70/095; H10W 70/635; H10W 70/664; H10W 70/69; H10W 74/15; H10W 90/00; H10W 90/724; H10W 90/733; H10W 90/734

(57) ABSTRACT

Provided is an electronic device, which includes a substrate, a via, a conductive element and a circuit structure. The via penetrates through the substrate and includes a first via and a second via. The conductive element is disposed in the via and includes a first conductive element and a second conductive element. The first conductive element is disposed in the first via. The second conductive element is disposed in the second via. The circuit structure is disposed on the substrate and is electrically connected to the conductive element. In a first direction, there is a first spacing between the two adjacent first conductive elements. There is a second spacing between the two adjacent second conductive elements. The first spacing is greater than the second spacing.

### CROSS-REFERENCE TO RELATED APPLICATION

This application claims the priority benefit of U.S. provisional application Ser. No. 63/704,566, filed on Oct. 8, 2024 and China application serial no. 202510674555.2, filed on May 23, 2025. The entirety of each of the above-mentioned patent applications is hereby incorporated by reference herein and made a part of this specification.

### BACKGROUND

### Technical Field

The disclosure relates to an electronic device, and particularly relates to a design of an electronic device having a via substrate and a manufacturing method thereof.

### Related Art

In a process of manufacturing an electronic device, since different materials configured to form the electronic device have different physical properties (such as thermal expansion coefficients), the manufactured electronic device may have a relatively poor yield. For example, a through glass via (TGV) substrate in the electronic device may easily crack due to a stress mismatch problem between different materials, resulting in a decrease in the yield of the electronic device.

### SUMMARY

The disclosure is related to an electronic device, or a design and a manufacturing method that can improve a yield of the electronic device.

According to some embodiments of the disclosure, the electronic device includes a substrate, a via, a conductive element, and a circuit structure. The via penetrates through the substrate and includes a first via and a second via. The conductive element is disposed in the via and includes a first conductive element and a second conductive element. The first conductive element is disposed in the first via. The second conductive element is disposed in the second via. The circuit structure is disposed on the substrate and electrically connected to the conductive element. In a first direction, there is a first spacing between the two adjacent first conductive elements. There is a second spacing between the two adjacent second conductive elements. The first spacing is greater than the second spacing.

According to some other embodiments of the disclosure, the electronic device includes a substrate, a via, a conductive element, and a circuit structure. The via penetrates through the substrate and includes a first via and a second via. The conductive element is disposed in the via and includes a first conductive element and a second conductive element. The first conductive element is disposed in the first via. The second conductive element is disposed in the second via. The circuit structure is disposed on the substrate and electrically connected to the conductive element. The first conductive element fills the first via. The second conductive element fills the second via.

### BRIEF DESCRIPTION OF THE DRAWINGS

FIG. 1A is a schematic partial top view of an electronic device according to an embodiment of the disclosure.

FIG. 1B is a schematic partial cross-sectional view of an electronic device along a section line A-A′ according to an embodiment of the disclosure.

FIG. 2 is a schematic flow chart of a manufacturing method of an electronic device according to a first embodiment of the disclosure.

FIG. 3 is a schematic flow chart of a manufacturing method of an electronic device according to a second embodiment of the disclosure.

FIG. 4 is a schematic flow chart of a manufacturing method of an electronic device according to a third embodiment of the disclosure.

FIG. 5 is a schematic flow chart of a manufacturing method of an electronic device according to a fourth embodiment of the disclosure.

FIG. 6 is a schematic flow chart of a manufacturing method of an electronic device according to a fifth embodiment of the disclosure.

FIG. 7 is a schematic partial cross-sectional view of a package structure according to an embodiment of the disclosure.

### DESCRIPTION OF THE EMBODIMENTS

The disclosure may be understood by referring to the following detailed description with reference to the accompanying drawings. It is noted that for comprehension of the reader and simplicity of the drawings, in the drawings of the disclosure, only a part of the electronic device is shown, and specific elements in the drawings are not necessarily drawn to scale. Moreover, the quantity and the size of each element in the drawings are only schematic and are not intended to limit the scope of the disclosure.

Throughout the specification and the appended claims of the disclosure, certain terms are used to refer to specific elements. Those skilled in the art should understand that electronic device manufacturers may probably use different names to refer to the same elements. This specification is not intended to distinguish between elements that have the same function but different names. In the following specification and claims, the terms “including”, “containing”, “having”, etc., are open-ended terms, so they should be interpreted to mean “including but not limited to . . . ”. Therefore, the terms “include”, “comprise”, and/or “have” used in the description of the disclosure denote the presence of corresponding features, regions, steps, operations, and/or elements but are not limited to the presence of one or more corresponding features, regions, steps, operations, and/or elements.

Directional terms, such as “upper”, “lower”, “front”, “rear”, “left”, “right”, mentioned in the disclosure are only directions with reference to the drawings. Therefore, the used directional terms are used to illustrate, but not to limit, the disclosure. In the drawings, each drawing illustrates the general features of a method, a structure, and/or a material used in a specific embodiment. However, the drawings should not be construed to define or limit the scope or nature covered by the embodiments. For example, for clarity, relative sizes, thicknesses, and positions of various film layers, regions, and/or structures may be reduced or enlarged.

When a corresponding component (for example, a film layer or a region) is referred to as being “on another component”, the component may be directly on the other component or there may be another component between the two. On the other hand, when a component is referred to as being “directly on another component”, there is no component between the two.

The terms “equal” or “same”, “substantially”, or “roughly” are generally interpreted as within 20% of a given value or range or interpreted as within 10%, 5%, or 0.5% of the given value or range.

Ordinal numbers such as “first” and “second” used in the specification and the claims are used to modify elements, and the terms do not imply and represent that the element(s) have any previous ordinal numbers, nor do they represent the order of a certain element and another element or the order of a manufacturing method. The use of the ordinal numbers is only to clearly distinguish between an element with a certain name and another element with the same name. The claims and the specification may not use the same terms, whereby a first component in the specification may be a second component in the claims.

It should be noted that in the following embodiments, features in several different embodiments may be replaced, recombined, and mixed to complete other embodiments without departing from the spirit of the disclosure. As long as the features of the various embodiments do not violate the spirit of the invention or conflict with each other, the features may be arbitrarily mixed and matched for use.

The electrical connection or coupling described in the disclosure may refer to either direct connection or indirect connection. In the case of direct connection, the terminals of two components on the circuit are directly connected or interconnected by a conductive line segment. In the case of indirect connection, there may be switches, diodes, capacitors, inductors, other suitable components, or combinations of the above between the terminals of two components on the circuit, but not limited thereto.

In the disclosure, the measurement manner of thickness, length, width, and area may be by adopting an optical microscope, and the thickness may be obtained by measuring a cross-sectional image in an electron microscope, but not limited thereto. In addition, there may be a certain error in any two values or directions for comparison. If a first value is equal to a second value, it implies that there may be an error of about 10% between the first value and the second value. If a first direction is perpendicular to a second direction, an angle between the first direction and the second direction may be between 80 degrees and 100 degrees; and if the first direction is parallel to the second direction, the angle between the first direction and the second direction may be between 0 degrees and 10 degrees.

A process of an electronic device of the disclosure may, for example, be provided through a wafer-level package (WLP) process or a panel-level package (PLP) process, which may be a chip first process or a chip last RDL first process.

The electronic device of the disclosure may be applied to power modules, semiconductor package devices, display devices, light-emitting devices, backlight devices, antenna devices, sensing devices, or tiling devices, but not limited thereto. It should be noted that the electronic device may be any arrangement or combination thereof, but not limited thereto. The electronic device may have driving systems, control systems, light source systems, and other peripheral systems to support display devices, antenna devices, wearable devices (for example, including augmented reality or virtual reality), vehicle-mounted devices (for example, including car windshields), or tiling devices. A manufacturing method of a package device in the disclosure may, for example, be applied to a wafer-level package (WLP) process or a panel-level package (PLP) process. The wafer-level package or the panel-level package process may include a chip-first process or a chip-last process, but not limited thereto. The electronic device may include package devices such as high bandwidth memory (HBM) packages, System on a Chip (SoC), System in a Package (SiP), Antenna in Package (AiP), Co-Packaged Optics (CPO), or various combinations of the foregoing devices, but not limited thereto.

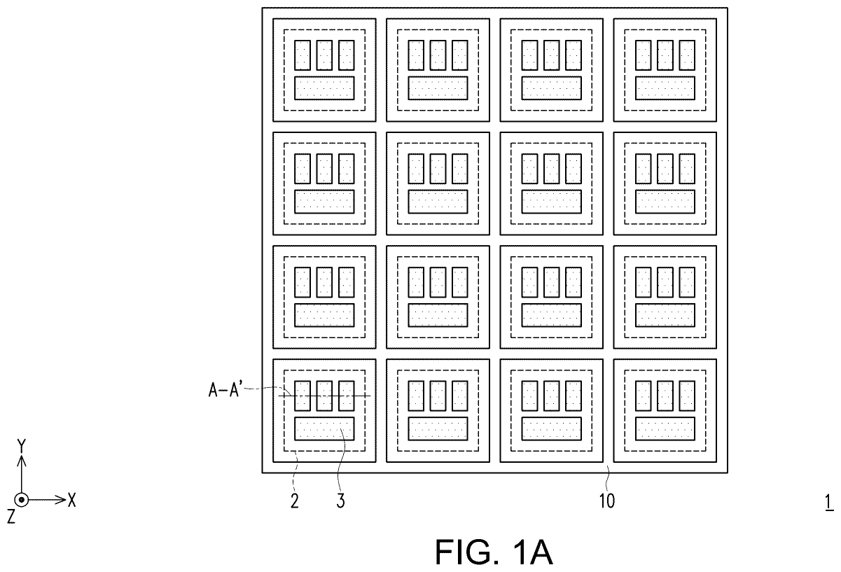

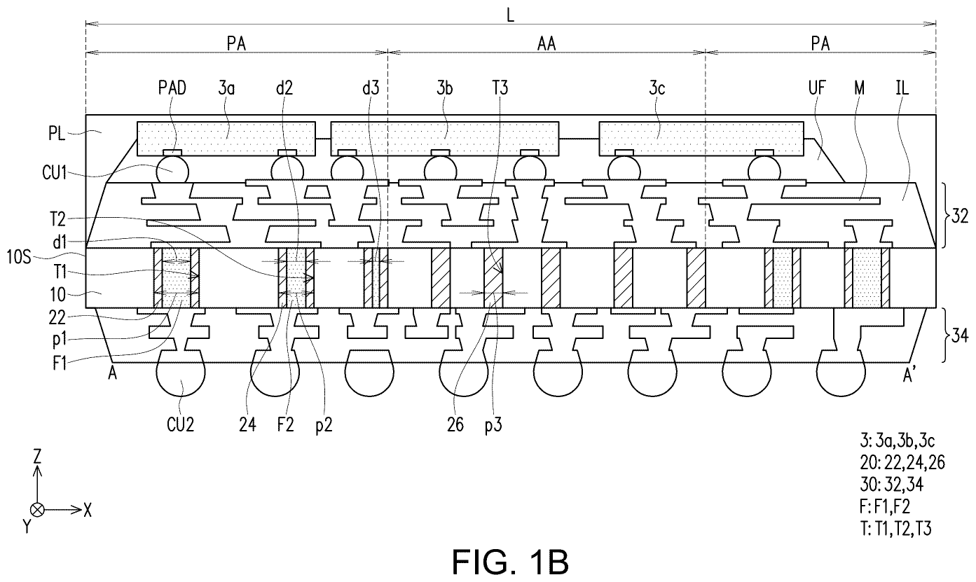

FIG. 1A is a schematic partial top view of an electronic device according to an embodiment of the disclosure. FIG. 1B is a schematic partial cross-sectional view of an electronic device according to an embodiment of the disclosure.

Please refer to FIG. 1A. An electronic device 1 of the embodiment has multiple electronic units 2 arranged in an array. Each of the electronic units 2 may be provided with multiple electronic elements 3 having same functions or different functions. From the perspective of FIG. 1B, in the embodiment, each of the electronic units 2 of the electronic device 1 may include a substrate 10, a via T, a conductive element 20, and a circuit structure 30.

A material of the substrate 10 may, for example, include a suitable ceramic material. For example, the material of the substrate 10 includes a transparent material, glass, alkali-free glass, or quartz glass. A thermal expansion coefficient of the substrate 10 may be greater than or equal to 3ppm/° C. and less than or equal to 10 ppm/° C. A light transmittance of the substrate 10 may be greater than or equal to 75%. Light may include white light, UV light, etc. In the embodiment, the substrate 10 is a glass substrate.

The via T, for example, penetrates through the substrate 10. In the embodiment, the via T includes a first via T1 and a second via T2 disposed in a peripheral region PA of the electronic device 1. The first via T1, for example, is away from a center of the electronic unit 2 relative to the second via T2. From another perspective, the first via T1 is away from an active region AA of the electronic device 1 relative to the second via T2. In the embodiment, an aperture p1 of the first via T1 in a direction X is greater than an aperture p2 of the second via T2 in the direction X. The direction X is a direction perpendicular to a normal direction (a direction Z) of the substrate 10. According to some embodiments, in the direction X, the substrate 10 has a width L. The peripheral region PA is a range with a distance of ¼*L from a side 10S of the substrate 10.

It is worth noting that the via T may further include a third via T3. The third via T3 is disposed in the active region AA of the electronic device 1. Based on this, the third via T3, for example, is closer to the center of the electronic unit 2 relative to the second via T2. In the embodiment, an aperture p3 of the third via T3 in the direction X is smaller than the aperture p2 of the second via T2 in the direction X. The aperture is the smallest width of the via in a cross section view.

The conductive element 20 is disposed in the via T. In some embodiments, the conductive element 20 may be conformally formed on the substrate 10. For example, the conductive element 20 may be disposed on at least a portion of a surface of the substrate 10, and, disposed in at least a portion of the via T. In the embodiment, the conductive element 20 includes a first conductive element 22 and a second conductive element 24. The first conductive element 22 is disposed in the first via T1. The second conductive element 24 is disposed in the second via T2. In the embodiment, the first conductive element 22 and the second conductive element 24 disposed in the first via T1 and the second via T2 may be signal transmission elements and/or heat dissipation elements. It is worth noting that the conductive element 20 may, further include a third conductive element 26. The third conductive element 26 is disposed in the third via T3, and may fill the third via T3.

In the embodiment, there is a first spacing d1 between the two adjacent first conductive elements 22 in the direction X. There is a second spacing d2 between the two adjacent second conductive elements 24 in the direction X. Since the aperture p1 of the first via T1 is greater than the aperture p2 of the second via T2, the first spacing d1 is greater than the second spacing d2. Similarly, the second spacing d2 may be greater than a third spacing d3 between adjacent conductive elements that are closer to a center of the active region AA.

The circuit structure 30 is disposed on the substrate 10, and electrically connected to the conductive element 20. In the embodiment, the circuit structure 30 is a redistribution structure. The definition of the redistribution structure is that at least one conductive layer M and at least one insulating layer IL may be included, which is configured to allow a circuit to be redistributed and/or further increase an area of a circuit fan-out. In addition, different electronic elements may be electrically connected to each other through the redistribution structure. For example, the redistribution structure is configured as a substrate for electrical interface routing between one connection and another connection. A formation manner of the redistribution structure may include: a stack of the at least one conductive layer M and the at least one insulating layer IL is provided. A formation method thereof includes that a process such as photolithography, etching, surface treatment, laser, electroplating is performed. Surface treatment includes that a surface of the at least one conductive layer M and/or the at least one insulating layer IL is roughened to enhance an adhesion capability thereof. A purpose of the redistribution structure is to extend a connection to a wider spacing or to redistribute a connection to another connection having a different spacing. In some embodiments, the insulating layer IL of the redistribution structure may be polyimide (PI), polyphenyl sulfide (PSPI), polybenzoxazole (PBO), epoxy, polymer, isophenylamine, silicon oxide (SiOₓ), or silicon nitride (SiNₓ).

In the embodiment, the circuit structure 30 includes a circuit structure 32 and a circuit structure 34. The circuit structure 32 and the circuit structure 34 are disposed relative to the substrate 10. In detail, the circuit structure 32 is disposed above the substrate 10 in a vertical direction Z. The circuit structure 34 is disposed below the substrate 10 in the vertical direction Z. The circuit structure 32 and the circuit structure 34 may be electrically connected to each other through the conductive element 20.

In the embodiment, the electronic device 1 further includes a filling material F. The filling material F is disposed in the via T. Alternatively, the filling material F may be configured to fill other portions of the via T not occupied by the conductive element 20. In detail, the filling material F includes a first filling material F1 and a second filling material F2. The first filling material F1 fills the first via T1. The second filling material F2 fills the second via T2. The filling material F may include a suitable composition of polymers, metals, alloys, graphene or silicon carbide. According to some embodiments, thermal expansion coefficients of the first filling material F1 and the second filling material F2 may be a same or different. The thermal expansion coefficient of the first filling material F1 may be less than the thermal expansion coefficient of the second filling material F2. According to some embodiments, Young's moduli of the first filling material F1 and the second filling material F2 may be same or different. The Young's modulus of the first filling material F1 may be less than the Young's modulus of the second filling material F2. The Young's modulus may be understood through a universal testing machine or other suitable testing methods.

Please refer to FIG. 1B. From another perspective, the via T may include the first via T1 and the second via T2 disposed in the peripheral region PA of the electronic device 1, and the third via T3 disposed in the active region AA of the electronic device 1. The first conductive element 22 and the second conductive element 24 in the first via T1 and the second via T2 may each be configured for signal transmission. The first filling material F1 and the second filling material F2 in the first via T1 and the second via T2 may each be configured for heat dissipation. The third conductive element 26 in the third via T3 may also be configured for signal transmission.

In the embodiment, the electronic device 1 further includes a connecting element CU1. The multiple electronic elements 3 may be electrically connected to the circuit structure 32 through a pad PAD and the connecting element CU1. The connecting element CU1 is disposed between the pad PAD and the circuit structure 32. A material of the connecting element CU1 may include copper, nickel, tin, silver, gold, gallium or other suitable materials. The multiple electronic elements 3 may, for example, be same electronic elements or different electronic elements. In some embodiments, the multiple electronic elements 3 may include common integrated circuits (IC), high bandwidth memory (HBM), flash memory, electronic integrated circuits (EIC), photonic integrated circuits (PIC), capacitors or other suitable electronic elements. In addition, the electronic device 1 further includes a connecting element CU2. The circuit structure 34 may be electrically connected to components such as an intermediate layer (not shown) through the connecting element CU2.

In the embodiment, the electronic device 1 further includes an intermediate layer UF. The intermediate layer UF is disposed between the multiple electronic elements 3 and the circuit structure 32. In detail, the intermediate layer UF may directly contact an active surface of the electronic elements 3, and fill a space between the two adjacent connecting elements CU1. A material of the intermediate layer UF may include a suitable inorganic material or an organic material.

In the embodiment, the electronic device 1 further includes an encapsulation layer PL. The encapsulation layer PL, for example, surrounds the multiple electronic elements 3. In some other embodiments, the encapsulation layer PL may cover the multiple electronic elements 3. According to some embodiments, the encapsulation layer PL may expose a back surface of the electronic elements 3 to facilitate heat dissipation of the electronic device 1. A material of the encapsulation layer PL may include epoxy molding compound (EMC).

In some embodiments, the electronic device 1 may be formed through performing a manufacturing method introduced in the following embodiments.

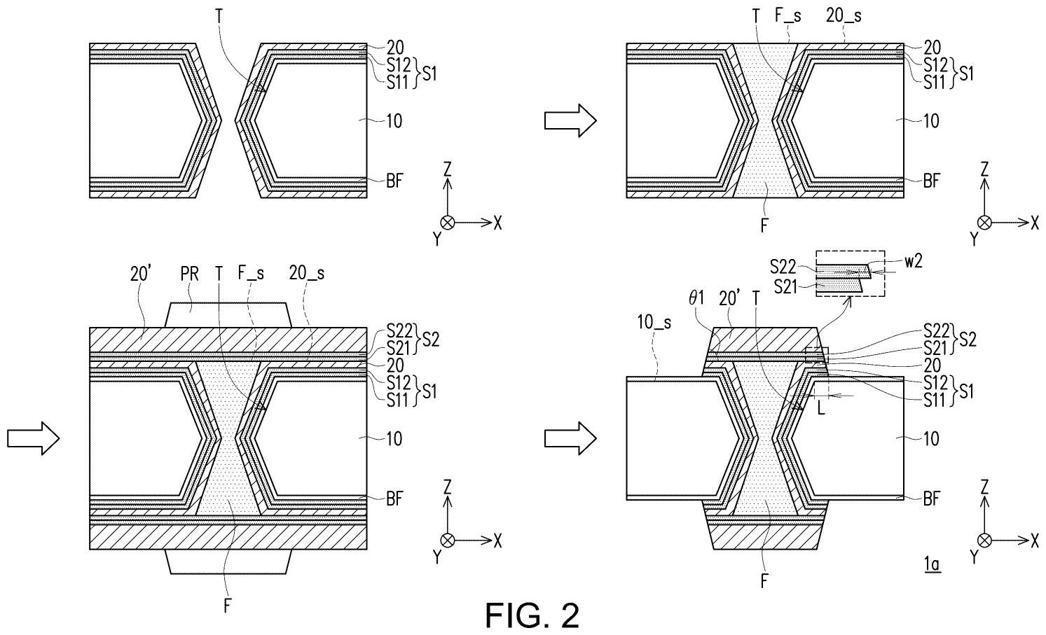

FIG. 2 is a schematic flow chart of a manufacturing method of an electronic device according to a first embodiment of the disclosure.

Please refer to FIG. 2. In the embodiment, an electronic device 1a may be formed through performing the following steps.

Step (1) is performed: the substrate 10 having the via T is provided.

In some embodiments, the via T may be formed through performing a laser modification, a drilling process, or an etching process. The substrate 10 may be formed through stacking two or more sub-substrates in conjunction with a stacking method such as heating, pressing, adhering, etc. For the remaining introduction of the substrate 10 and the via T, please refer to the foregoing embodiments, which will not be elaborated here. According to some embodiments, sub-substrates with vias formed may be stacked. Alternatively, the sub-substrates may be stacked first, and then the vias are formed.

Step (2) is performed: a buffer layer BF is formed on the substrate 10.

In some embodiments, the buffer layer BF may be formed through performing a suitable deposition process, such as PVD, CVD, PECVD, printing, coating, or any other suitable method. Through an arrangement of the buffer layer BF, the buffer layer BF may cover a side of the substrate 10 or a sidewall of the via T. Furthermore, the buffer layer BF may fill pits, unevenness, or micro-cracks generated on a corresponding surface of the substrate 10 during the process to reduce a possibility of defects generated in a subsequently formed seed layer S1 and/or the conductive element 20. In some embodiments, a material of the buffer layer BF may include a suitable organic material and/or an inorganic material. For example, the material of the buffer layer BF may include polyimide (PI), parylene, benzocyclobutene (BCB), epoxy, polycarbonate (PC), polyethylene terephthalate (PET), polyethylene naphthalate (PEN), or a silicon-containing compound. In some embodiments, the buffer layer BF may include a multi-layer structure. The buffer layer BF may include a stack structure of inorganic layer/organic layer/inorganic layer. In some embodiments, the buffer layer BF may have a toughness of 0.1 kJ/m² to 100 kJ/m².

According to some embodiments, through a formation of the buffer layer BF, a roughness of the surface of the substrate 10 or the sidewall of the via T may be relatively reduced. For example, the surface roughness of the substrate 10 may be less than or equal to 5 microns. A surface roughness of the buffer layer BF may be less than or equal to 3 microns. In some embodiments, a determination of roughness is defined by using a scanning electron microscope (SEM) or a transmission electron microscope (TEM) to observe a side of each substrate 10. If a difference between a peak and a valley of an undulation of a side surface is 0.15 μm-1 μm, it may be considered as low roughness. The SEM or the TEM may observe a condition of a surface undulation of a side of each sub-substrate with vias at a same appropriate magnification, and may compare the condition of undulation by taking a unit length (such as 10 μm). The “appropriate magnification” means that at least 10 undulation peaks may be seen on at least one surface in a field of view at this magnification.

Step (3) is performed: the seed layer S1 is formed on the substrate 10.

The seed layer S1 may be disposed on the buffer layer BF. The seed layer S1 may be formed through a suitable deposition process, such as chemical plating, electroplating, atomic layer deposition (ALD), physical vapor deposition (PVD), chemical vapor deposition (CVD), or plasma enhanced chemical vapor deposition (PECVD), but is not limited thereto. The seed layer S1 may include a seed layer S11 and a seed layer S12 that are sequentially stacked. In some embodiments, a material of the seed layer S11 and a material of the seed layer S12 may include titanium nitride, titanium, copper, tungsten, or ruthenium.

Step (4) is performed: the conductive element 20 is formed on the substrate 10.

The conductive element 20 may, for example, be disposed on the seed layer S1. In some embodiments, the conductive element 20 may be formed through a chemical plating process, an electroplating process. For the remaining introduction of the conductive element 20, please refer to the foregoing embodiments, which will not be elaborated here. In the embodiment, the conductive element 20 has a thickness of 2 microns to 40 microns.

Step (5) is performed: the filling material F is formed on the substrate 10.

The filling material F may, for example, fill the via T. In some embodiments, the filling material F may be formed through a suitable deposition process, such as coating, injection. In the embodiment, a surface F_s of the filling material F exposed by the via T may be substantially flush with a surface 20_s of the conductive element 20. For the remaining introduction of the filling material F, please refer to the foregoing embodiments, which will not be elaborated here.

Step (6a) is performed: a seed layer S2 is formed on the substrate 10.

The seed layer S2 may, for example, be disposed on the surface F_s of the filling material F and the surface 20_s of the conductive element 20. In other words, the seed layer S2 may cover the surface F_s of the filling material F and the surface 20_s of the conductive element 20. In some embodiments, the seed layer S2 may be formed through a suitable deposition process. The seed layer S2 may include a seed layer S21 and a seed layer S22 that are sequentially stacked.

Step (7a) is performed: a mask pattern PR is formed on the substrate 10.

The mask pattern PR may, for example, be disposed on the conductive element 20′, and may, for example, expose a portion of the conductive element 20′. In the embodiment, the mask pattern PR at least overlaps with the via T. In some embodiments, the mask pattern PR may be formed through sequentially performing a suitable coating process, an exposure process, and a development process. A material of the mask pattern PR may include a suitable organic material.

Step (8a) is performed: the mask pattern PR is used to perform an etching process on the conductive element 20′, the seed layer S2, the conductive element 20, and the seed layer S1.

In some embodiments, the etching process performed on the conductive element 20′, the seed layer S2, the conductive element 20, and the seed layer S1 may be a wet etching process. An etching solution used in the wet etching process may include hydrofluoric acid. In the embodiment, the seed layer S2 after undergoing the wet etching process may include a taper angle θ1. The taper angle θ1 may, for example, be 35 degrees to 90 degrees.

In the embodiment, multiple etching processes are sequentially performed on surfaces of the conductive element 20′, the seed layer S2, the conductive element 20, and the seed layer S1 exposed by the mask pattern PR. Since an etching selectivity to hydrofluoric acid differs between the seed layer S21 and the seed layer S22 of the seed layer S2, the seed layer S2 may include an undercut. In detail, at least one side of the seed layer S22 protrudes beyond the seed layer S21 in the direction X. Alternatively, both sides of the seed layer S22 protrude beyond the seed layer S21 in the direction X. A width w2 of a portion where the at least one side of the seed layer S22 protrudes beyond the seed layer S21 in the direction X may, for example, be 0.1 microns to 1 micron. Similarly, the seed layer S1 may also include an undercut for the foregoing reason. According to some embodiments, both sides of the seed layer S2 may include undercuts. In detail, in the direction X, both sides of the seed layer S22 protrude beyond the seed layer S21. That is to say, a projection length of the seed layer S22 is greater than a projection length of the seed layer S21. The width w2 of a portion where both sides of the seed layer S22 protrude beyond the seed layer S21 in the direction X may, for example, be 0.1 microns to 1 micron.

In the embodiment, the seed layer S11 has a thickness of 0.5 microns to 50 microns. In addition, the seed layer S11 after undergoing the etching process has a length L in the direction X on a surface 10_s of the substrate 10. The length L is 5 times the thickness of the seed layer S11 to 20 times the thickness of the seed layer S11. Therefore, an adhesion capability between the seed layer, the conductive element, and the buffer layer BF may be enhanced.

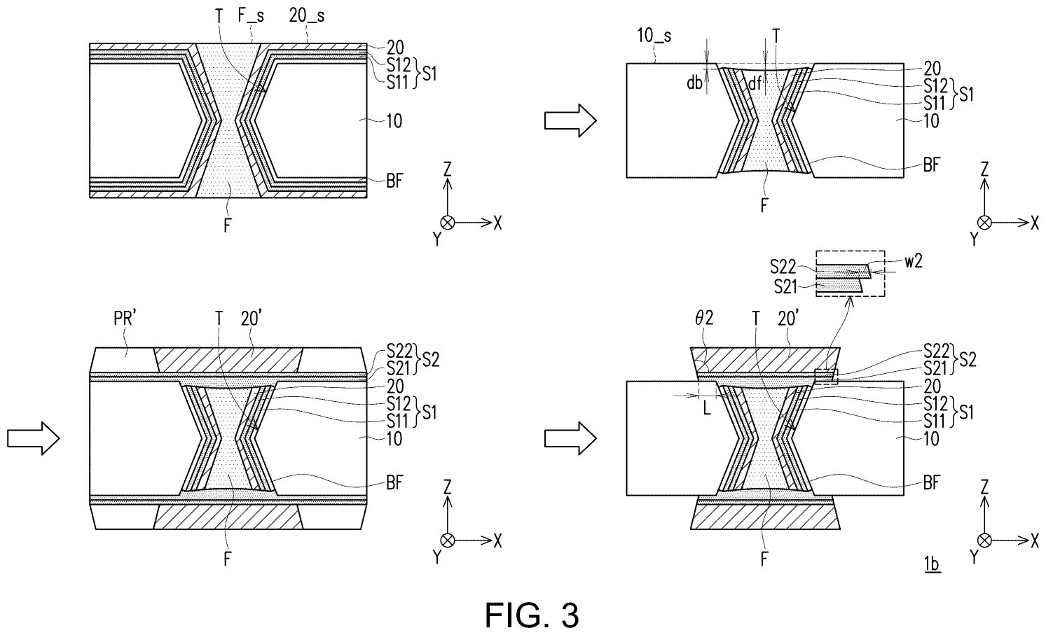

FIG. 3 is a schematic flow chart of a manufacturing method of an electronic device according to a second embodiment of the disclosure. It should be noted that the embodiment in FIG. 3 uses the reference numerals and part of the contents of the embodiment in FIG. 2. The same numerals are used to denote the same or similar elements, and the description of the same technical content is omitted.

Please refer to FIG. 3. In the embodiment, an electronic device 1b may be formed through performing the following steps.

Step (1) to step (5) are performed. The detailed steps thereof may be referred to in the foregoing embodiment, and will not be elaborated here.

Step (6b): a thinning process is performed to expose the surface 10_s of the substrate 10.

In detail, a portion of the filling material F, the conductive element 20, the seed layer S1, and the buffer layer BF on two opposite sides of the substrate 10 may be removed through the thinning process, exposing the surface 10_s of the substrate 10. In some embodiments, the thinning process performed may include a polishing process and/or a dry etching process.

In the embodiment, since a material of the substrate 10 has relatively large characteristic differences compared to materials of the buffer layer BF, the filling material F, the conductive element 20, and the seed layer S1, after performing the thinning process, the buffer layer BF, the filling material F, the conductive element 20, and the seed layer S1 that are located in the via T may present a step relative to the substrate 10. In the embodiment, a distance db between a surface of the buffer layer BF and the surface 10_s of the substrate 10 in the vertical direction Z is 0.1 nanometers to 200 nanometers. A distance df between a surface of the filling material F and the surface 10_s of the substrate 10 in the vertical direction Z is 0.1 nanometers to 2000 nanometers, 0.5 nanometers to 1000 nanometers, 2 nanometers to 800 nanometers, or 10 nanometers to 500 nanometers. Through a design where the buffer layer BF, the filling material F, the conductive element 20, and the seed layer S1 present the step relative to the substrate 10, an adhesion capability between the conductive element 20′ and the seed layer S2 may be enhanced.

Step (6a) is performed: the seed layer S2 is formed on the substrate 10.

In the embodiment, the seed layer S2 covers the substrate 10 and the buffer layer BF, the filling material F, the conductive element 20, and the seed layer S1 located in the via T. In detail, the seed layer S2 may fill the step generated between the buffer layer BF, the filling material F, the conductive element 20 and the seed layer S1 that are located in the via T and the substrate 10. For the remaining introduction of the seed layer S2, please refer to the foregoing embodiment, which will not be elaborated here.

Step (7b) is performed: a mask pattern PR′ is formed on the substrate 10.

The mask pattern PR′ is disposed on the seed layer S2 and exposes a portion of the seed layer S2. In the embodiment, the mask pattern PR′ does not overlap with the via T, and at least exposes the seed layer S2 that overlaps with the via T. In some embodiments, the mask pattern PR′ may be formed through sequentially performing a suitable coating process, an exposure process, and a development process.

Step (9) is performed: the conductive element 20′ is formed on the substrate 10.

The conductive element 20′ is, for example, disposed in a space defined by the mask pattern PR′. In detail, the conductive element 20′ overlaps with at least a portion of the via T. The conductive element 20′ is disposed on the seed layer S2 that overlaps with the via T and is exposed by the mask pattern PR′. In some embodiments, the conductive element 20′ may be formed by performing a chemical plating process, or an electroplating process. In the embodiment, the conductive element 20′ has a thickness of 2 microns to 60 microns. For the remaining introduction of the conductive element 20′, please refer to the descriptions regarding the conductive element 20 in the foregoing embodiment, which will not be elaborated here.

In the embodiment, the conductive element 20′ defined by the mask pattern PR′ may include a taper angle θ2. The taper angle θ2 may, for example, be 80 degrees to 120 degrees.

Step (10) is performed: the conductive element 20′ is used to perform an etching process on the seed layer S2.

It is worth noting that, in the embodiment, the mask pattern PR′ is removed before the etching process is performed.

In the embodiment, multiple wet etching processes are sequentially performed on surfaces of the seed layer S22 and the seed layer S21 exposed by the mask pattern PR. Due to a different etching selectivity to hydrofluoric acid between the seed layer S21 and seed layer S22 of the seed layer S2, the seed layer S2 may include an undercut. In detail, the width w2 of a portion where the seed layer S22 protrudes beyond the seed layer S21 in the direction X may be 0.1 microns to 1 micron.

In the embodiment, the seed layer S21 has a thickness of 0.5 microns to 50 microns. In addition, the seed layer S21 after undergoing the etching process has the length L in the direction X on the surface 10_s of the substrate 10. The length L is 5 times the thickness of the seed layer S21 to 20 times the thickness of the seed layer S21.

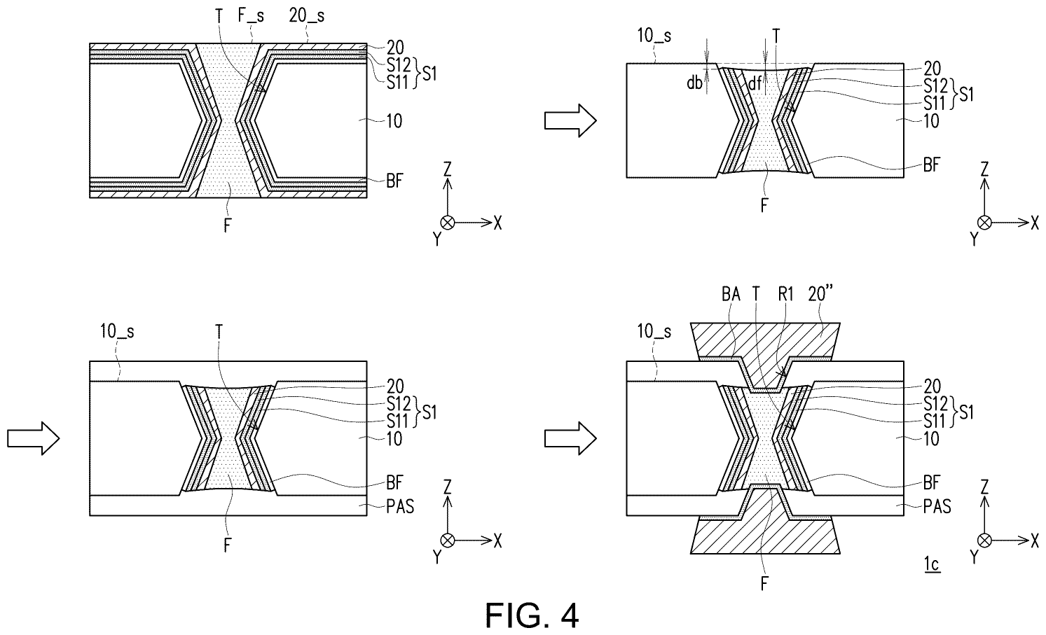

FIG. 4 is a schematic flow chart of a manufacturing method of an electronic device according to a third embodiment of the disclosure. It should be noted that the embodiment in FIG. 4 uses the reference numerals and part of the contents of the embodiment in FIG. 3. The same numerals are used to denote the same or similar elements, and the description of the same technical content is omitted.

Please refer to FIG. 4. In the embodiment, an electronic device 1c may be formed through performing the following steps.

Step (1) to step (6b) are performed. The detailed steps thereof may be referred to in the foregoing embodiment, and will not be elaborated here. It is worth noting that, in the embodiment, the filling material F is a conductive material.

Step (11) is performed: an insulating layer PAS is formed on the substrate 10.

In some embodiments, the insulating layer PAS may be formed by a suitable process method. In the embodiment, the insulating layer PAS covers the substrate 10 and the buffer layer BF, the filling material F, the conductive element 20 and the seed layer S1 that are located in the via T. In detail, the insulating layer PAS may fill the step generated between the buffer layer BF, the filling material F, the conductive element 20 and the seed layer S1 that are located in the via T and the substrate 10.

Step (12) is performed: a portion of the insulating layer PAS is removed on the substrate 10 to expose at least a portion of the filling material F.

A method of removing the insulating layer PAS may include laser, etching, plasma treatment, photolithography process, or using a mask pattern (not shown) to perform an etching process on the insulating layer PAS to form a recess R1 to expose at least a portion of the filling material F. However, the removal method is not limited thereto.

Step (13) is performed: a conductive element 20″ is formed on the substrate 10.

The conductive element 20″ is, for example, disposed in the recess R1 of the insulating layer PAS. In detail, the conductive element 20″ overlaps with at least a portion of the via T and is disposed on the filling material F exposed by the insulating layer PAS, which is electrically connected to the filling material F and may form a path for signal transmission. In some embodiments, the conductive element 20″ may be formed by performing a suitable deposition process. In the embodiment, before the conductive element 20″ is formed, a barrier layer BA may be formed first in the recess R1 of the insulating layer PAS and on a portion of a surface of the insulating layer PAS. A material and a formation method of the barrier layer BA may be a same as or similar to the seed layer S1. The barrier layer BA also includes an undercut.

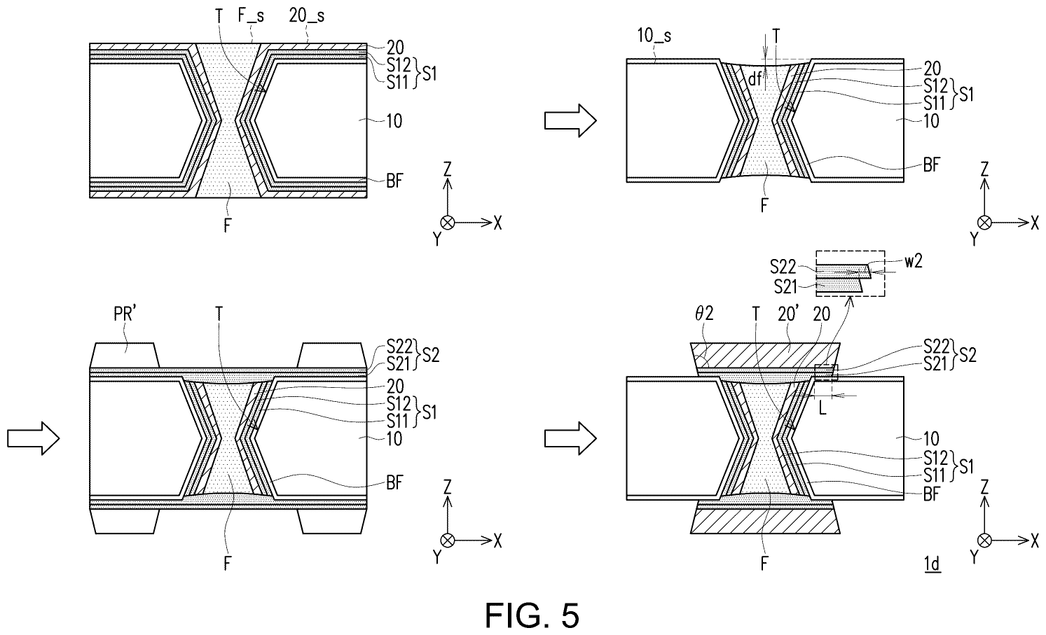

FIG. 5 is a schematic flow chart of a manufacturing method of an electronic device according to a fourth embodiment of the disclosure. It should be noted that the embodiment in FIG. 5 uses the reference numerals and part of the contents of the embodiment in FIG. 3. The same numerals are used to denote the same or similar elements, and the description of the same technical content is omitted.

Please refer to FIG. 5. A main difference between a formation method of an electronic device 1d of the embodiment and the formation method of the foregoing electronic device 1b is that: the buffer layer BF located on the surface 10_s of the substrate 10 is not completely removed in step (6b).

In the embodiment, after the thinning process is performed, a portion of the buffer layer BF still remains on the surface 10_s of the substrate 10. Therefore, there are no steps between the buffer layer BF and the substrate 10.

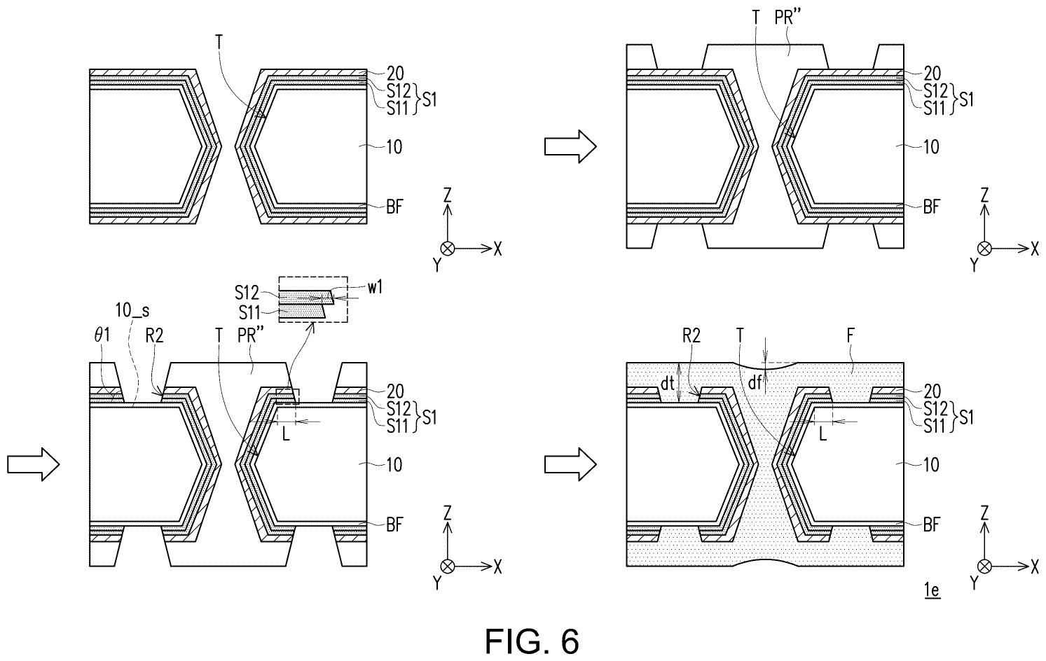

FIG. 6 is a schematic flow chart of a manufacturing method of an electronic device according to a fifth embodiment of the disclosure. It should be noted that the embodiment in FIG. 6 uses the reference numerals and part of the contents of the embodiment in FIG. 2. The same numerals are used to denote the same or similar elements, and the description of the same technical content is omitted.

Please refer to FIG. 6. In the embodiment, an electronic device 1e may be formed through performing the following steps.

Step (1) to step (4) are performed. The detailed steps thereof may be referred to in the foregoing embodiments and will not be elaborated here.

Step (7c) is performed: a mask pattern PR″ is formed on the substrate 10.

In the embodiment, the mask pattern PR″ is disposed on the seed layer S1, and filled in the via T, and exposes a portion of the seed layer S1. In the embodiment, the mask pattern PR″ fills the via T, and the exposed seed layer S1 does not overlap with the via T.

Step (8b) is performed: the mask pattern PR″ is used to perform an etching process on the conductive element 20 and the seed layer S1.

In some embodiments, the etching process performed on the conductive element 20 and the seed layer S1 is a wet etching process. An etching solution used in the wet etching process includes hydrofluoric acid. In the embodiment, the seed layer S1 after undergoing the wet etching process may include the taper angle θ1. The taper angle θ1 may, for example, be 35 degrees to 90 degrees.

In the embodiment, multiple etching processes are sequentially performed on surfaces of the conductive element 20 and the seed layer S1 exposed by the mask pattern PR″. Due to a different etching selectivity to hydrofluoric acid between the seed layer S11 and the seed layer S12 of the seed layer S1, the seed layer S1 may include an undercut. In detail, the seed layer S12 protrudes beyond the seed layer S11 in the direction X. The width w1 of a portion where the seed layer S12 protrudes beyond the seed layer S12 in the direction X may be 0.1 microns to 1 micron.

In the embodiment, after the wet etching process is performed on the conductive element 20 and the seed layer S1, a recess R2 is formed that exposes a portion of the buffer layer BF.

In the embodiment, the seed layer S11 has a thickness of 0.5 microns to 50 microns. In addition, the seed layer S11 after undergoing the etching process has the length L in the direction X on the surface 10_s of the substrate 10. The length L is 5 times the thickness of the seed layer S11 to 20 times the thickness of the seed layer S11.

Step (14) is performed: the filling material F is formed on the substrate 10. In the embodiment, the filling material F may, for example, fill the via T, and fill the recess R2. In some embodiments, the filling material F may be formed through performing a suitable deposition process. Since a depth of the recess R2 is less than a depth of the via T (or a thickness of the substrate 10), the filling material F overlapping with the via T in the vertical direction Z has a recess. A maximum depth df of the recess is 0.1 nanometers to 100 nanometers.

A distance dt between a top surface of the filling material F and the buffer layer BF exposed by the recess R2 is 15 microns to 50 microns.

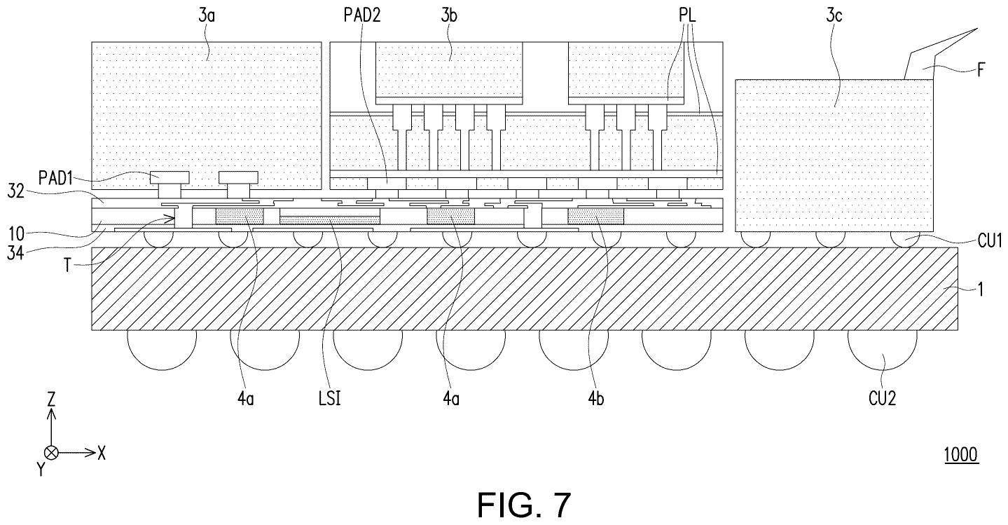

FIG. 7 is a schematic partial cross-sectional view of a package structure according to an embodiment of the disclosure. It should be noted that the embodiment in FIG. 7 uses the reference numerals and part of the contents of the embodiments in FIG. 1 to FIG. 6. The same numerals are used to denote the same or similar elements, and the description of the same technical content is omitted.

In the embodiment, an electronic device 1000 may include the substrate 10, the via T, the circuit structure 30 and multiple electronic elements that are different from or the same to each other disposed on a circuit board 1, implementing a 2.5D package structure with multiple electronic elements horizontally placed side by side. Furthermore, the electronic device 1000 includes multiple electronic elements embedded in the substrate 10, which will be described in detail later, thereby providing better integration capability.

In the embodiment, the package structure 1000 includes three electronic elements 3a, 3b, and 3c. The electronic element 3a may, for example, be a high bandwidth memory (HBM), and may be electrically connected to the electronic elements embedded in the substrate 10 (such as an electronic element 4a or an electronic element 4b) through a pad PAD1 and the circuit structure 30 (such as a redistribution structure). The electronic element 3b may, for example, be a system-on-integrated-chips (SoIC) and is packaged by the encapsulation layer PL, and may be electrically connected to the electronic elements embedded in the substrate 10 through a pad PAD2 and the circuit structure 30. The electronic element 3c may be a photonic integrated circuit (PIC), which may be electrically connected to the electronic elements embedded in the substrate 10 through a connecting element CU1 and the circuit structure 30, and may establish a communication path through an optical fiber F.

In the embodiment, the package structure 1000 includes the electronic elements embedded in the substrate 10, such as the electronic element 4a or the electronic element 4b. The electronic element 4a may be an embedded deep trench capacitor (eDTC). The electronic element 4b may be an integrated voltage regulator (IVR).

In the embodiment, the circuit board 1 may also include the electronic device 1a, the electronic device 1b, the electronic device 1c, the electronic device 1d or the electronic device 1e of the foregoing embodiments. According to some embodiments, the circuit board 1 may have at least one other via T′. In the direction X, a width of the other via T′ may be greater than a width of the via T of the substrate 10. According to some embodiments, a thickness of the substrate included in the circuit board 1 is greater than a thickness of the substrate 10. According to some embodiments, a Young's modulus of the substrate of the circuit board 1 is greater than a Young's modulus of the substrate 10. Through the foregoing design, the circuit board 1 may carry more elements or may improve the reliability of the electronic device. According to some embodiments, the circuit board 1 may include glass.

In summary, in the manufacturing method of the electronic device provided in some embodiments of the disclosure, the conductive elements formed on the substrate are in a non-continuous form. Therefore, multiple portions having different structures may be formed on an upper surface and/or a lower surface of the substrate, which allows the stress generated when the electronic device is heated to be matched in order to improve a yield of the electronic device.

What is claimed is:

1. An electronic device, comprising:
a substrate;
a via, penetrating through the substrate, and comprising a first via and a second via;
a conductive element, disposed in the via, and comprising a first conductive element and a second conductive element, wherein the first conductive element is disposed in the first via, and the second conductive element is disposed in the second via; and
a circuit structure, disposed on the substrate and electrically connected to the conductive element,
wherein, in a first direction, there is a first spacing between the two adjacent first conductive elements, there is a second spacing between the two adjacent second conductive elements, and the first spacing is greater than the second spacing.

2. The electronic device according to claim 1, wherein a filling material is disposed in the via.

3. The electronic device according to claim 2, wherein the filling material comprises an organic material.

4. The electronic device according to claim 2, wherein the filling material comprises graphene or silicon carbide.

5. The electronic device according to claim 2, wherein the conductive element in the via is configured for signal transmission, and the filling material in the via is configured for heat dissipation.

6. The electronic device according to claim 1, wherein in the first direction, the first via has a first aperture, the second via has a second aperture, and the first aperture is greater than the second aperture.

7. The electronic device according to claim 1, further comprising:
a seed layer, disposed on the conductive element, wherein the seed layer comprises:
a first seed layer; and
a second seed layer, disposed on the first seed layer,
wherein at least one side of the second seed layer protrudes beyond the first seed layer in the first direction.

8. The electronic device according to claim 7, wherein a width of a portion where the second seed layer protrudes beyond the first seed layer in the first direction is 0.1 microns to 1 micron.

9. The electronic device according to claim 7, wherein the second seed layer comprises a taper angle, and the taper angle is 35 degrees to 90 degrees.

10. The electronic device according to claim 7, further comprising:
another conductive element, disposed on the seed layer, and overlapping with at least a portion of the via.

11. The electronic device according to claim 6, wherein the second conductive element comprises a taper angle, and the taper angle is 80 degrees to 120 degrees.

12. The electronic device according to claim 2, wherein there is a distance between a surface of the filling material and a surface of the substrate in a vertical direction, and the vertical direction is perpendicular to the first direction.

13. The electronic device according to claim 12, wherein the distance between the surface of the filling material and the surface of the substrate in the vertical direction is 0.1 nanometers to 200 nanometers.

14. An electronic device, comprising:
a substrate;
a via, penetrating through the substrate, and comprising a first via and a second via;
a conductive element, disposed in the via, and comprising a first conductive element and a second conductive element, wherein the first conductive element is disposed in the first via, and the second conductive element is disposed in the second via; and
a circuit structure, disposed on the substrate and electrically connected to the conductive element,
wherein the first conductive element fills the first via, and the second conductive element fills the second via.

15. The electronic device according to claim 14, wherein the conductive element overlaps with the filling element in a vertical direction, and the filling element has a recess.

16. The electronic device according to claim 14, wherein a maximum depth of the recess is 0.1 nanometers to 100 nanometers.

17. The electronic device according to claim 14, wherein in a first direction, the first via has a first aperture, the second via has a second aperture, and the first aperture is greater than the second aperture.

18. The electronic device according to claim 14, further comprising:
a seed layer, disposed on the conductive element, wherein the seed layer comprises:
a first seed layer; and
a second seed layer, disposed on the first seed layer,
wherein the second seed layer protrudes beyond the first seed layer in a first direction.

19. The electronic device according to claim 18, wherein a width of a portion where the second seed layer protrudes beyond the first seed layer in the first direction is 0.1 microns to 1 micron.

20. The electronic device according to claim 19, further comprising:
a buffer layer, disposed on the substrate, and located between the substrate and the conductive element.
